(19) United States
(12) Patent Application Publication
(10) Pub. No.: US 2012/0264311 A1
(43) Pub. Date: Oct. 18, 2012

(54) SURFACE TREATMENT METHOD FOR GERMANIUM BASED DEVICE

(75) Inventors: Xia An, Beijing (CN); Yue Guo, Beijing (CN); Runsheng Wang, Beijing (CN); Ru Huang, Beijing (CN); Xing Zhang, Beijing (CN)

(73) Assignee: PEKING UNIVERSITY, Beijing (CN)

(21) Appl. No.: 13/318,644

(22) PCT Filed: Apr. 8, 2011
(86) PCT No.: PCT/CN11/72518

§ 371 Date: Nov. 3, 2011

(30) Foreign Application Priority Data
Sep. 1, 2010 (CN) 201010269030.4

(51) Int. Cl. C23G 1/02; C09K 15/02; H01L 21/31; B08B 3/08

(52) U.S. Cl. 438/778; 134/3; 252/387; 257/E21.24

(57) ABSTRACT

The present invention provides a surface treatment method for germanium based device. Through performing surface pretreatment to the germanium based device by using an aqueous solution of ammonium fluoride as a passivant, the interface state may be reduced, the formation of natural oxidation layer at the germanium surface may be inhibited, the regeneration of natural oxidation layer and the out-diffusion of the germanium based substrate material can be effectively inhibited, and the thermal stability of the metal germanide may also be increased significantly, so that the interface quality of the germanium based device is improved easily and effectively, which are advantageous to improve the performance of the germanium based transistor.

### FIELD OF THE INVENTION

The present invention relates to the field of ultra large scale integrated circuit (ULSI) fabrication technology, in particular to a surface treatment method for a germanium based device.

### BACKGROUND OF THE INVENTION

The integrated circuit technology has followed the Moore's law for over 40 years, and results in the rapid improvement of integrate circuit in the integration degree and performance, the reduction in the dimensional size of a metal-oxide-semiconductor field effect transistor (MOSFET) is a major means to improve operation speed and reduce production cost. However, with further shrinkage of the device feature size, the transistor gradually reaches both the physical limit and the technical limit, so that it is difficult to improve the performance of conventional Si device at a speed as before. Introduction of channel material with high mobility may further improve the device performance, thus currently, a germanium based device has become a hot topic in research. Compared with silicon material, the hole mobility of germanium material under a low electric field is 4 times larger, and the electron mobility of germanium material is 2 times larger. Therefore, as a novel channel material, germanium based material becomes one of the hopeful development directions for high speed MOSFET device due to the higher and more symmetric carrier mobility thereof.

However, currently the fabrication technology of a germanium based device has not been fully developed, the performance of the device is still not very ideal and there are still a lot of problems to be solved. Firstly, the interface of a germanium based device presents an interface state with relatively high density and the scattering is increased, which result in the degraded mobility of the germanium based device. Secondly, at a relatively low temperature (330° C.), an out-diffusion phenomenon may occur in a germanium based substrate material, that is, germanium diffuses toward outside of the substrate in the form of germanium monoxide gas, which results in that the morphology of the surface of the germanium based substrate and the film deposited thereon becomes worse and lead to increased current leakage. Thirdly, the thermal stability of the metal germanide film is relatively poor, and the metal germanide film may be condensed to form a lot of cavities in the metal germanide film due to a nucleation and condensation reaction so that the property of the film becomes worse. Above problems adversely affect the characteristics of the germanium based device and cause difficulties to the fabrication process of the germanium based device.

### SUMMARY OF THE INVENTION

In order to solve the above-mentioned problems, the present invention provides a passivant for a surface of a germanium based device and a method for performing surface pretreatment to a germanium based device by using the passivant. The method is advantageous to improve the performance of the fabricated device, the process is simple, the cost is low, and the effect is significant. By performing surface pretreatment to a germanium based device using the passivant, the interface state may be reduced and the regeneration of natural oxidation layer and the out-diffusion of the germanium based substrate material can be effectively inhibited. The thermal stability of the metal germanide may also be improved significantly.

A passivant for a surface of a germanium based device is characterized in that the passivant is an aqueous solution of ammonium fluoride, the concentration of which is in the range of 20-55% by weight.

A method for performing surface pretreatment to a germanium based device by using an ammonium fluoride solution as a passivant comprises the following steps:

1) using a semiconductor germanium based substrate as a substrate;

2) cleaning the substrate;

3) removing an oxidation layer on the surface;

4) performing surface treatment to the substrate by using the aqueous solution of ammonium fluoride under atmospheric environment for 5-35 minutes.

In step 1), the germanium based substrate may be a bulk germanium substrate, an epitaxial germanium substrate or a germanium on insulator (GOI) substrate. The substrate may be N type doped or P type doped.

In step 2), the cleaning step may be an organic cleaning, a HCl cleaning, a HF cleaning, etc. for removing organic and inorganic contaminants, metal particles and so on from the substrate, but the present application is not limited to the above mentioned cleaning methods.

In step 3), the process for removing the surface oxidation layer is implemented by immersing the substrate into a solution of HCl, HF or HBr.

After step 4), a metal film such as nickel, platinum or cobalt, etc. may be further deposited and may be subjected to a reactive annealing to form metal germanide. The process temperature of the reactive annealing is in the range from 300 to 600° C., and the annealing time is in the range from 10 to 70 seconds. Silicon dioxide or other high-K dielectric layer, such as Al₂O₃, ZrO₂, Y₂O₃, etc., may also be deposited.

Compared with conventional technology, beneficial effects of the present invention are as follow.

Firstly, through performing surface pretreatment to the germanium based device by using the aqueous solution of ammonium fluoride, fluorine with high electronegativity may be introduced onto the surface of the germanium based device, and stable Ge—F bonds are easily formed. Therefore, the surface pretreatment by the ammonium fluoride may passivate the germanium surface and reduce the influence of interface state. Secondly, during the film deposition and the annealing, the surface of germanium based device that has been subjected to the pretreament by the ammonium fluoride may be prevented from generating and volatileness of germanium monoxide gas and the out-diffusion of germanium is obviously reduced, so that a smooth and uniform surface is obtained. Thirdly, since the out-diffusion of germanium may be aggravated due to the presence of a natural oxidation layer so as to damage the surface of the germanium based device, it is necessary to remove the natural oxidation layer before the film deposition. However, once exposed to the atmosphere, the natural oxidation layer will be regenerated. The regeneration of the natural oxidation layer may be effectively inhibited by means of the ammonium fluoride pretreatment process, and the surface quality may be further improved. Fourthly, the ammonium fluoride pretreatment may also effectively inhibit the metal germanide from condensing and forming cavities under a higher annealing temperature, and significantly improve the thermal stability of the metal germanide. Fifthly, by means of the present method, the interface characteristics of the germanium based device are improved easily and effectively, the performance of the germanium based transistor is improved, and the surface passivation pretreatment is performed to the germanium based device without increasing the complexity of the process, which is very advantageous for process integration.

### BRIEF DESCRIPTION OF THE DRAWINGS

FIG. 1 is a flow chart illustrating a specific embodiment of performing surface pretreatment to a germanium based device by using the passivant according to the present invention.

FIG. 2 illustrates SEM photographs of the surfaces of metal germanide films prepared by using three surface pretreatment methods.

FIG. 3 illustrates SEM photographs of metal germanide films formed at different annealing temperatures after being subjected to a surface pretreatment by using ammonium fluoride.

### DETAILED DESCRIPTION OF THE EMBODIMENTS

Hereinafter, the beneficial effects of performing surface pretreatment to a germanium based device by using an ammonium fluoride solution as a passivant are illustrated with reference to the accompanying drawings and a specific embodiment.

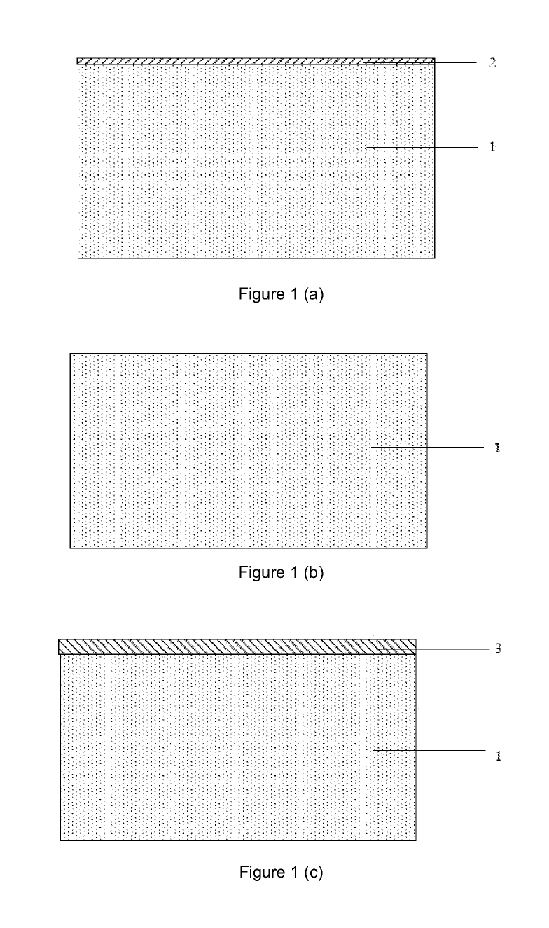

FIG. 1 is a flow chart illustrating a method of a specific embodiment for performing surface pretreatment to a germanium based device by using an ammonium fluoride solution as a passivant. The present embodiment comprises the following steps.

Step 1: a germanium based substrate is provided. As shown in FIG. 1(a), a semiconductor germanium substrate 1 is provided, wherein the semiconductor germanium substrate 1 may be a bulk germanium substrate, an epitaxial germanium substrate or a germanium on insulator (GOI) substrate, etc. The substrate may be P type doped or N type doped. On the surface of the semiconductor substrate 1, there may be a natural oxidation layer 2 which has a thickness of about 1 nm.

Step 2: a cleaning process is performed to the substrate. Firstly, an organic cleaning is performed to the substrate, wherein the substrate is washed for two times alternately by acetone and alcohol and then is repeatedly rinsed with DI water (Deionized water), so that greasy dirt and organic contaminant on the substrate are removed. Subsequently, a HCl cleaning is performed, wherein the substrate is heated in a boiled diluted hydrochloric acid and then is repeatedly rinsed with DI water, so that inorganic contaminant and metal particles are removed. The purpose of cleaning is to remove the organic and inorganic contaminant as well as metal particles and so on, and the cleaning method is not limited to above mentioned cleaning methods.

Step 3: the surface oxidation layer is removed. A method of immersing the substrate into a solution of HCl or a diluted solution of HF and then repeatedly rinsing the substrate with DI water until the substrate is clean. The schematic diagram of the substrate after being removed the oxidation layer is shown in FIG. 1(b).

Step 4: an ammonium fluoride surface pretreatment is performed. Under the atmospheric environment, the substrate is immersed into an aqueous solution of ammonium fluoride for 5-35 minutes, wherein the concentration of the aqueous solution of ammonium fluoride is 40%. Subsequently, the substrate is repeatedly rinsed with DI water until it is clean so as to accomplish the pretreatment to the surface of the germanium based device.

Step 5: a metal film is deposited and an annealing is performed to form metal germanide, and in the present embodiment a metal nickel film is deposited. The beneficial effects of performing pretreatment to the surface of the germanium based device by using the ammonium fluoride as a passivant are demonstrated by the specific embodiment. A layer of metal nickel is deposited on the semiconductor substrate by means of physical vapor deposition, such as evaporation, sputtering or electron beam evaporation and so on, wherein the nickel layer may be a nickel metal layer or a nickel alloy layer. The thickness of the metal film deposited is about 10 nm to 50 nm. After the deposition of the nickel film, a capping layer may be optionally formed on the nickel layer according to the method of the present invention. Subsequently, an annealing treatment is performed, wherein the rapid thermal annealing is performed so that the above mentioned metal film is reacted with the germanium layer thereunder to form metal germanide 3, as shown in FIG. 1(c). Further, the temperature of this rapid thermal annealing process is in the range from 350 to 600° C., and the annealing time is 30 to 80 seconds, depending on the thickness of the nickel metal layer deposited.

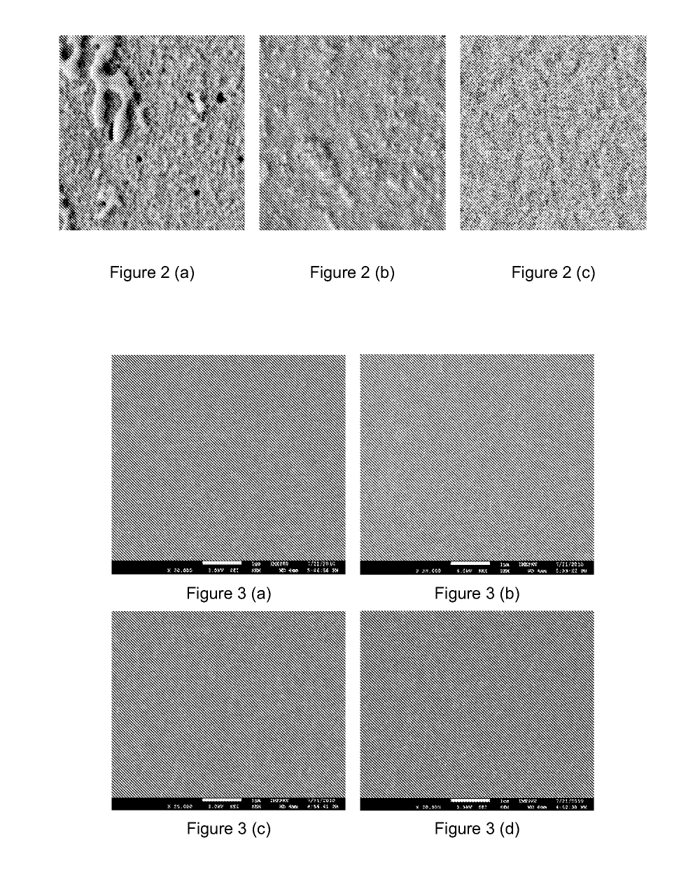

FIG. 2 illustrates SEM photographs of the surfaces of metal germanide films prepared by using three surface pretreatment methods. The flow of preparing the metal germanide films are shown in FIG. 1. With respect to FIG. 2(a), only the process of removing the surface oxidation layer by using HCl is performed, whereas the process of surface treatment by using the ammonium fluoride as a passivant is not performed. It can be seen from the figure that obvious condensation occurs in the resulted NiGe film while a lot of cavities are formed, so that the film is coarse and the quality of the film is poor. Therefore, an excellent film can not be obtained by only removing the natural oxidation layer using HCl. With respect to FIG. 2(b), only the process of removing the surface oxidation layer by using HF is performed, whereas the process of surface treatment by using the ammonium fluoride as a passivant is not performed. It can be seen from the figure that the property of the film is improved, but the condensation phenomenon still exists and the resulted nickel germanide film is not smooth. FIG. 2(c) shows an embodiment of the present invention, wherein the surface oxidation layer is removed first by using HCl and then subjected to the surface treatment by using the ammonium fluoride as a passivant. After using the ammonium fluoride as a passivant, the surface morphology of the film is improved significantly, the surface is smooth and uniform. It is mainly because the regeneration of the natural oxidation layer may be inhibited after using the ammonium fluoride as a passivant while the volatileness of the germanium monoxide gas may be inhibited by the ammonium fluoride during the annealing so that the out-diffusion of germanium is reduced and the condensation of the metal germanide may be prevented, and thus a very smooth surface can be obtained. With comparison, the beneficial effects of performing surface pretreatment to the germanium based device by using ammonium fluoride as a passivant can be clearly shown.

FIG. 3 illustrates SEM photographs of a nickel germanium film at different annealing temperatures after being subjected to surface pretreatment by using the ammonium fluoride. The flow of preparing the metal germanide films are shown in FIG. 1, wherein the annealing temperatures from (a) to (d) are 350° C., 400° C., 450° C. and 500° C. respectively, and the annealing times are all 40 s. It can be seen from the figures that, after performing surface pretreatment to the germanium based device by using the ammonium fluoride as the passivant, the nickel germanium films in the temperature range of 350 to 500° C. all possess excellent film quality. Therefore, the thermal stability of the nickel germanium film may be significantly improved by ammonium fluoride passivant.

In an embodiment of the present invention, the passivant for the surface of the germanium based device is an aqueous solution of ammonium fluoride with a concentration of 40% by weight, however, the concentration of the aqueous solution of ammonium fluoride may range from 20 to 55% by weight. By using the passivant according to the present invention and the method for performing surface pretreatment to a germanium based device by using the passivant, the interface state may be reduced, the formation of natural oxidation layer at the germanium surface may be inhibited, the volatileness of germanium monoxide may be reduced, and the thermal stability of the formed metal germanide may also be improved, which are advantageous to improve the performance of a germanium based transistor. Therefore, compared with conventional process and technology, the present invention may improve the electrical property and the reliability of the germanium based device easily and effectively.

A passivant according to the present invention and a method for performing surface pretreatment to a germanium based device by using the passivant are illustrated and demonstrated by above preferred embodiments. Those skilled in the art should understand that, the above mentioned embodiment is merely a preferred embodiment of the present invention, and the preparation method and application thereof are not limited to the content disclosed in the embodiment, and any equivalent changes and modifications made according to the claims of the present invention without departing from the substantive scope of the present invention should belong to the scope of the present invention.

What is claimed is:

1. A usage of an aqueous solution of ammonium fluoride as a passivant for a surface of a germanium based device, wherein the concentration of the ammonium fluoride is 20-55% by weight.

2. A surface pretreatment method for a surface of a germanium based device, comprising the following steps:
1) using a semiconductor germanium based substrate as a substrate;
2) cleaning the substrate;
3) removing an oxidation layer on the surface;
4) performing a surface treatment to the substrate by using an aqueous solution of ammonium fluoride, wherein, the concentration of the ammonium fluoride in the aqueous solution of ammonium fluoride is 20-55% by weight, the time of the surface treatment is 5-35 minutes, and the surface treatment is performed under atmospheric environment.

3. The method according to claim 2, characterized in that, the germanium based substrate is a bulk germanium substrate, an epitaxial germanium substrate or a germanium on insulator substrate.

4. The method according to claim 2, characterized in that, in step 2), the cleaning step is organic cleaning, HCl cleaning or HF cleaning.

5. The method according to claim 2, characterized in that, in step 3), the process for removing the surface oxidation layer is implemented by immersing the substrate into a solution of HCl, HF or HBr.

6. The method according to claim 2, characterized in that, after step 4), a metal film, such as nickel, platinum and cobalt, film is further deposited and reacted to generate metal germanide, or a silicon dioxide or other high-K dielectric layer, such as Al₂O₃, ZrO₂ and Y₂O₃, is further deposited.
